(19) United States
(12) Patent Application Publication
(10) Pub. No.: US 2026/0262435 A1
(43) Pub. Date: Sep. 3, 2026

(54) PROCESS FOR THE FORMATION OF A PEROVSKITE LAYER IN PARTICULAR FOR A PHOTOVOLTAIC CELL

(71) Applicant: SINGULUS TECHNOLOGIES AG, Kahl am Main (DE)

(72) Inventor: Mirza CORDA, Maisach (DE)

(73) Assignee: SINGULUS TECHNOLOGIES AG, Kahl am Main (DE)

(21) Appl. No.: 19/489,919

(22) PCT Filed: Jul. 23, 2024
(86) PCT No.: PCT/EP2024/070938

§ 371 Date: Dec. 4, 2025

(30) Foreign Application Priority Data
Aug. 1, 2023 (DE) 10 2023 120 384.3

(51) Int. Cl. H10K 71/15; H10F 10/17; H10F 71/00; H10K 30/40; H10K 85/50

(52) U.S. Cl. CPC H10K 71/15; H10F 71/00; H10F 10/17; H10K 30/40; H10K 85/50

(57) ABSTRACT

A method for forming a perovskite layer on a carrier substrate and a method for manufacturing a solar cell having such a perovskite layer. The method includes mixing a solution which contains a first and a second perovskite precursor at a mixing temperature, applying the solution to the carrier substrate, moving the carrier substrate together with the applied solution in a two-dimensional movement and simultaneously cooling the carrier substrate together with the applied solution to a deposition temperature below the carrier substrate starting temperature in order to produce a deposited layer which contains the first and the second perovskite precursor on the carrier substrate.

### FIELD

The present invention relates to a method for forming a perovskite layer. The invention further relates to a method for manufacturing a solar cell having a perovskite layer formed in this way.

### BACKGROUND

Perovskite layers, i.e., thin layers of perovskite material, may have interesting electrical and optical properties, among other things, because of which they are suitable for a wide variety of applications.

In particular, solar cells have recently been developed in which an absorber layer of perovskite material is used for absorbing light and for photovoltaic conversion of energy contained in the light into electrical energy. Such so-called perovskite solar cells promise high efficiencies with low material costs and simple manufacture.

Various methods are known for forming perovskite layers, in particular for solar cells.

For example, chemical substances which may react with one another to form a perovskite material and which are also referred to herein as perovskite pre-product, perovskite precursors or perovskite starting materials may be applied to a substrate in a single process step and then chemically reacted there, for example, by supplying energy in the form of, for example, heat. In such a single-stage process, the perovskite layer precursors may be vapor-deposited onto a substrate, for example, in a common vapor deposition process, which is also referred to as co-evaporation. However, such vapor deposition processes are often difficult to implement on an industrial scale, require complex apparatuses and/or are cost-intensive. Alternatively, wet-chemical deposition processes for forming a perovskite layer in a single-stage process have been proposed. However, technical difficulties and/or high costs often also impede an industrial implementation of these methods.

Alternatively, perovskite precursors may be applied to a substrate in a two-stage process before they are then again chemically reacted. In this case, first a first perovskite precursor layer is applied to a substrate and then a second perovskite precursor layer is applied thereover.

In order to form the two perovskite precursor layers, different technologies may again be used.

For example, a perovskite precursor layer may be formed by deposition of chemical substances suitable for this purpose by means of physical vapor deposition (PVD), such as, for example, co-evaporation, or by means of chemical vapor deposition (CVD). However, complex apparatuses are generally necessary for this purpose, wherein high costs and/or low throughputs associated therewith often make such methods of industrial implementation uninteresting.

Alternatively, at least one of the perovskite precursor layers may be formed by means of wet-chemical methods. In this case, use of different wet-chemical deposition methods is conceivable.

For example, a so-called spin coating is often used on a laboratory scale in order to apply a viscous solution, in which the substances required for the perovskite precursor are contained, to a rotating substrate, which solution is then distributed there on account of acting centrifugal forces to form a perovskite layer precursor layer of homogeneous thickness. However, such an approach is usually usable only for coating small-area substrates and, owing to lack of mass suitability, in particular is not of interest for industrial implementation for forming perovskite layers.

As an alternative, perovskite layers may also be applied wet-chemically with the aid of so-called extrusion slot dies. Such methods are also referred to as slot-die-coating. In this case, a solution which should be sufficiently viscous and in which the substances required for the perovskite precursor are again contained is extruded through a wide slot die onto a surface of a substrate. However, a relatively high outlay in terms of apparatus required for this purpose and restrictions on the viscous solutions usable in this case do not make industrial implementation of such deposition methods for forming perovskite layers appear to be of interest.

In addition, in the two wet-chemical deposition methods mentioned above, the starting materials are frequently dissolved in solvents such as, for example, dimethylformamide, which are relatively hazardous hazardous substances which are, for example, flammable and/or toxic. This may make industrial implementation of the methods mentioned more difficult, for example, because of high costs or the need for complex apparatuses. In particular, when designing a plant to be used for this purpose, many safety aspects such as, for example, taking account of regulations (e.g. ATEX) may lead to an increase in cost. The solvents themselves are also frequently expensive, as a result of which production costs of the overall process may be increased.

In a further approach, the starting materials are dissolved in a solvent and applied to a substrate by a spraying method, which is also referred to as spray coating. However, aerosols are generally generated here which, on the one hand, may be complicated to remove by suction and/or because of which a proportion of the starting materials used does not pass into the perovskite layer to be generated, as a result of which an efficiency of the deposition is reduced.

### SUMMARY

There may therefore be a need for an alternative approach with the aid of which a perovskite layer may be formed and with the aid of which at least some of the abovementioned problems of previous approaches may be avoided or reduced. In particular, there may be a need for a method with the aid of which a perovskite layer may be produced with low costs, low outlay in terms of apparatus and/or in a manner which may be easily implemented industrially. In addition, there may be a need for a method for manufacturing a solar cell in which such a method is used for forming a perovskite layer.

The abovementioned needs may be at least partially satisfied with the subject matter of one of the independent claims of the present application. Advantageous embodiments are specified in the dependent claims and in the description below.

According to a first aspect of the present invention, a method for forming a perovskite layer on a carrier substrate is described. The method has at least the following process steps, preferably in the specified order:
(i) mixing a solution which contains a first and a second perovskite precursor at a mixing temperature,
(ii) applying the solution to the carrier substrate, which is optionally temperature-controlled to a carrier substrate starting temperature,
(iii) moving the carrier substrate together with the applied solution in a two-dimensional movement and simultaneously cooling the carrier substrate together with the applied solution to a deposition temperature below the mixing temperature in order to produce a deposited layer which contains both the first and the second perovskite precursor and/or a reaction product from the two perovskite precursors on the carrier substrate,
(iv) optionally: removing a non-deposited proportion of the solution from the carrier substrate, and
(v) optionally: heating the deposited layer above a drying temperature above the deposition temperature in order to dry the solution and/or to initiate a chemical reaction between the first perovskite precursor and the second perovskite precursor and/or a conversion of the reaction product formed therefrom.

According to a second aspect of the present invention, a method for manufacturing a solar cell is described. The method has at least the following process steps, preferably in the specified order:
forming a perovskite layer on a surface of a carrier substrate by means of the method according to an embodiment of the first aspect of the invention, and
forming electrical contacts for discharging electrical charge carriers from the perovskite layer.

Embodiments of the invention may be considered, inter alia and without restricting the invention, to be based on ideas or observations described below.

In the introduction, a basic concept for embodiments of the invention described herein will be explained briefly, wherein this explanation is to be interpreted as merely roughly summarizing and not limiting the invention:

As already indicated, the aim is to provide an advantageous and in particular industrially usable process for forming perovskite layers, for example for manufacturing solar cells.

For this purpose, a preferably single-stage wet-chemical process is proposed herein. In this case, a solution in which a first perovskite precursor and a second perovskite precursor are taken up or dissolved is mixed in advance. In this case, the solution is temperature-controlled to a mixing temperature which is generally increased relative to an ambient temperature. In this case, the mixing temperature is preferably selected such that a reaction occurs between the first and second perovskite precursors contained in the solution, wherein a reaction product may correspond to the perovskite to be formed with regard to its chemical composition and possibly also with regard to its structural structure. This solution is then applied to the carrier substrate, wherein the carrier substrate may also be temperature-controlled to a so-called carrier substrate starting temperature which is typically increased relative to the ambient temperature. The carrier substrate provided with the applied solution in this way is subsequently successively cooled to a lower deposition temperature and simultaneously moved in a special two-dimensional manner. As a result of the successive cooling, the reaction product formed from the two perovskite precursors may precipitate out of the solution and accumulate on the surface of the carrier substrate, preferably in the form of a layer and furthermore preferably in a crystalline form. As a result of the simultaneous movement of the carrier substrate and the solution located thereon, it may be achieved that a layer formed in this case forms uniformly and with a homogeneous layer thickness. As soon as a sufficient layer thickness has been achieved in this case, an excess proportion of the solution which has not been taken up in the deposited layer may be removed from the carrier substrate. Finally, the layer deposited in this way may optionally be heated again, for example in order to evaporate residues of the solution remaining therein and/or in order to convert previously unconverted proportions of the first and second perovskite precursors into the reaction product, with the result that the desired perovskite layer is formed overall.

The proposed approach may be implemented in this case using a technically relatively simple plant and/or in a manner which may be implemented industrially. Furthermore, hazardous, harmful and/or expensive solvents may be dispensed with. Furthermore, no aerosols generally arise in the proposed preferably single-stage wet-chemical process.

Possible features of configurations of the invention and advantages to be achieved therewith are described in detail below.

Perovskite layers may be used for different technical applications. Accordingly, different perovskite materials may be used in an application-specific manner.

Perovskite solar cells generally consist of different layers. Here, an absorber layer of the type ABX₃ may be used as the main layer, wherein “A” stands for cesium (Cs), methylammonium (MA) or formamidinium (FA), “B” stands for lead (Pb) and “X” stands for chlorine, bromine or iodine. For example, MAPbl₃ (methylammonium lead iodide) may be used for the perovskite layer of a solar cell.

The perovskite layer to be formed with the method described herein may in principle be produced with any desired dimensions. For example, an area of the perovskite layer may be between a few square millimeters up to several square meters. Preferably, an area of the perovskite layer may be between 5 cm² and 5 m², more preferably between 200 cm² and 2 m². Here, a layer thickness may be between 1 nm and 1 mm, preferably between 100 nm and 1 μm. Here, the perovskite layer is generally not self-supporting, but rather is supported by a carrier substrate.

The carrier substrate may in principle have any desired dimensions and consist of any desired material. For example, the carrier substrate may have the same area dimensions as the perovskite layer to be formed thereon. However, the carrier substrate may also have a larger area than the perovskite layer to be formed, with the result that the latter covers only partial areas of the carrier substrate. The carrier substrate generally has a significantly greater thickness than the perovskite layer. For example, the thickness of the carrier substrate is usually greater than 0.1 mm, often greater than 0.5 mm, greater than 1 mm or even greater than 3 mm, but generally less than 2 cm or less than 1 cm.

A material and a geometry of the carrier substrate may be selected such that, on the one hand, it mechanically supports the perovskite layer sufficiently to be able to withstand the forces acting on the perovskite layer during operation. On the other hand, the carrier substrate should be able to withstand the conditions occurring during the formation of the perovskite layer, such as, for example, temperatures, attacks by chemicals used, etc. Furthermore, a coefficient of thermal expansion of the carrier substrate should not differ excessively from that of the perovskite layer formed thereon. In practice, thin glass panes have proven to be suitable for the carrier substrate for many applications. However, carrier substrates of semiconductor material, in particular in the form of silicon plates or wafers, may also be used. As described in more detail further below, for example, an already finished processed solar cell, for example a solar cell constructed from a silicon wafer, may serve as carrier substrate. In principle, however, carrier substrates of other materials are also conceivable, for example of plastic, ceramic, metal, etc.

In the method described herein, a solution which contains both a first and a second perovskite precursor is first mixed. In this case, the two perovskite precursors are typically completely dissolved in a liquid solvent and/or mixed with the latter. One of the perovskite precursors may possibly also be chemically bound in the solvent. In this case, the solution may be saturated to a certain extent with the first and/or the second perovskite precursor, for example to an extent of more than 10%, more than 30%, more than 60%, more than 80%, more than 90%, more than 95% or even with complete saturation or even supersaturation. In this case, the solution is temperature-controlled to a first temperature T1, which is referred to herein as mixing temperature T1. This mixing temperature is typically increased relative to an ambient temperature and is selected such that a reaction occurs between the first and second perovskite precursors in order to form the desired perovskite or at least one chemically equivalent precursor thereof as reaction product. The mixing temperature may therefore also be referred to as reaction temperature. For example, the mixing temperature may be at least 50° C., at least 60° C. or at least 70° C. In this case, the mixing temperature depends, among other things, on properties of the two perovskite precursors and/or properties of the solvent. In this case, a solubility of the perovskite precursors, i.e. an amount of material which may be dissolved maximally in the solution up to complete saturation of the solution, typically increases with increasing mixing temperature.

After the solution has been mixed in advance and temperature-controlled in this way, it is applied to a surface of the carrier substrate. For example, the solution may be applied dropwise, poured, casted or applied in some other way to the carrier substrate. In this case, a sufficient amount of solution is preferably applied in order to wet the entire surface of the carrier substrate or at least a partial surface on which the perovskite layer is to be formed with solvent over the entire area and in a sufficient thickness. An amount of solvent which is applied to the carrier substrate, or an amount of material of the two perovskite precursors contained therein, is preferably greater or even significantly greater (i.e. for example more than 10%, more than 20% or even more than 50% greater) than an amount of material of the perovskite layer ultimately to be formed on the carrier substrate. In other words, solvent may be applied in excess to the carrier substrate.

In this case, the carrier substrate is preferably temperature-controlled at least initially to an increased second temperature T2, which is referred to herein as carrier substrate starting temperature T2. This carrier substrate starting temperature may be similar to the mixing temperature, but need not be identical to the mixing temperature. The carrier substrate starting temperature may possibly be up to 20° C., up to 10° C. or at least up to 5° C. greater or less than the mixing temperature. The carrier substrate starting temperature is preferably slightly lower than the mixing temperature, for example by between 1° C. and 20° C., preferably by between 3° C. and 10° C.

The carrier substrate covered in this way with the solution is then set into a two-dimensional movement. In the case of such a two-dimensional movement, the carrier substrate is successively displaced transversely in different directions and/or rotated or pivoted rotationally about different axes. Such a two-dimensional movement may also be referred to as wobbling movement or as wobbling. On account of such a two-dimensional movement of the carrier substrate, it may be achieved that the solution applied to the surface thereof is distributed uniformly and ultimately forms a homogeneous layer.

Simultaneously with the two-dimensional movement, the carrier substrate together with the solution applied thereon is successively cooled down to a third temperature T3, which is referred to herein as deposition temperature T3. Here, the deposition temperature is preferably significantly below the carrier substrate starting temperature. For example, the deposition temperature may be at least 10° C., preferably at least 20° C. or even at least 30° C. below the carrier substrate starting temperature. For example, the deposition temperature may be less than 40° C. In this case, the deposition temperature to be achieved depends on properties of the perovskite precursors or reaction products contained in the solution and of the solvent and in particular on a solubility of the perovskite precursors or reaction products in the solvent of the solution. As a result of the successive cooling to the deposition temperature which is lower in comparison with the carrier substrate starting temperature, in this case the temperature-dependent solubility of the two perovskite precursors or reaction products in the solution is reduced, with the result that these at least partially precipitate out of the solution and therefore deposit as a layer on the surface of the carrier substrate.

After a desired layer thickness of the layer deposited in this way from the first and second perovskite precursors and/or the reaction product has been produced, a non-deposited residue of the solution is generally removed from the carrier substrate, for example by the latter being poured off.

The carrier substrate with the layer produced in this way, which is formed from the two perovskite precursors and/or the reaction product formed from the perovskite precursors, may subsequently be heated again in a targeted manner. In particular, in this case heating is carried out above a predetermined fourth temperature T4, which is referred to herein as drying temperature T4. This drying temperature may be selected such that remaining solvent evaporates or volatilizes. Furthermore, the drying temperature may depend in a material-specific manner on the properties of the first and second perovskite precursors or of the reaction product and may represent a temperature above which a conversion and/or chemical reaction occurs between the two perovskite precursors, with the result that these ultimately form the desired perovskite layer. The drying temperature may therefore also be referred to as reaction temperature limit. This reaction temperature limit is usually significantly above the deposition temperature, for example by more than 5° C. or even more than 10° C. For example, the reaction temperature limit may be above 50° C., above 60° C. or above 70° C., but usually below 150° C., below 130° C. or below 90° C. In the case of the abovementioned heating, evaporation of residues of the solvent contained in the solution possibly occurs simultaneously.

According to an embodiment, the solution is aqueous, wherein the first and second perovskite precursors and/or the reaction product are soluble in aqueous solution. The aqueous solution may comprise water as solvent. Alternatively or additionally, the aqueous solution may comprise an aqueous solution of an acid. An aqueous solution is usually easy to handle and inexpensive to provide. In particular, the aqueous solution should be free of harmful, hazardous and/or difficult to dispose of chemicals. Here, both the first and the second perovskite precursor and the reaction product should preferably be water-soluble. A solubility of the two perovskite precursors and/or of the reaction product should in each case be sufficiently high in order to be able to dissolve a sufficient amount of each of the two perovskite precursors and/or reaction products in the solution in order ultimately to be able to produce the perovskite layer therefrom in a desired thickness. In particular, the solubilities of the perovskite precursors in the solution may be different, but they should be similar to one another within acceptable tolerances. For example, the solubilities of the two perovskite precursors in the solution may differ from one another by less than 50%, preferably less than 20% or less than 10%.

For example, according to an embodiment, the first perovskite precursor may contain cesium, methylammonium or formamidinium. In particular, the first perovskite precursor may contain methylammonium iodide. The second perovskite precursor may contain lead, in particular lead acetate and/or a lead halide. These first and second perovskite precursors were recognized, on the one hand, as being suitable for forming a perovskite layer, in particular a perovskite layer of the ABX₃ type. On the other hand, these first and second perovskite precursors have a sufficiently high solubility in an aqueous solvent. Accordingly, an easy-to-handle and inexpensive mixture of water and such a perovskite precursor to which, for example, no other chemicals or at least only small amounts of other chemicals are added may be used as solution.

According to an embodiment, the solution may contain hydrogen halide as solvent. Such hydrogen halide may be provided as hydroiodic acid (HI), hydrochloric acid (HCl, also referred to as muriatic acid) or hydrobromic acid (HBr). The solvent may therefore be a chemical compound which itself comprises one of the perovskite precursors, for example in the form of a halogen such as iodine, chlorine or bromine. Mixtures of hydrogen halides may also be used. Aqueous solutions of such hydrogen halides may usually be handled using industrially well-established methods and plants and may be neutralized relatively easily, for example with the formation of salts.

According to an embodiment, the solution is mixed separately from the carrier substrate in a mixing tank and temperature-controlled to the mixing temperature. In other words, the first and second perovskite precursors do not come into contact for the first time during or after the application of the solution to the carrier substrate, but are already mixed in advance with one another and with the solvent in a mixing tank to be provided separately and temperature-controlled to the desired mixing temperature. Here, the mixing temperature is preferably selected to be so high that chemical reactions to reaction products already occur between the perovskite precursors within the mixing tank. For this purpose, a suitable agitator or the like may be provided in the mixing tank in order to be able to mix the components of the solution with one another as homogeneously as possible. Furthermore, a heater or the like may be provided in the mixing tank in order to temperature-control the entire solution to the mixing temperature.

In addition, gas, in particular inert gas, may be applicable to the mixing tank. In this case, an increased gas pressure may be adjustable in order, for example, to accelerate a metering of precursors. Here, the solution should be distributed as quickly and uniformly as possible on the substrate. For this purpose, the two-dimensional movement may already be effected during the transfer of the solution from the mixing tank to the substrate. In addition, for example, an amount to be delivered or a liquid jet may be delivered or divided by a device in a targeted manner into a region of the substrate in order to initially reach a plurality of regions of the substrate. In addition, a larger volume may optionally be applied without liquid with high kinetic energy impinging on the substrate in a punctiform manner. Possible damage to sensitive underlying layers is thereby avoided and a more homogeneous wetting for the initial deposition is achieved. In addition, a device for providing a required amount may be provided, for example as a metering pump, a gravity metering, a control of a switching time of a valve, etc. The volume may be measured e.g. with an impeller meter or ultrasonic flow meter.

According to an embodiment, during the production of the deposited layer, process parameters including a process duration and a temporal temperature profile during the cooling to the deposition temperature are selected such that the deposited layer is produced as a crystalline layer. In other words, process parameters which influence a way in which the deposited layer is produced from the two perovskite precursors and/or the reaction product may be set in a targeted manner such that the deposited layer is produced as a crystalline layer, i.e. crystallization occurs during the deposition. Such process parameters include, inter alia, the temperature of the solution and in particular a temporal profile with which this temperature is reduced in the course of the cooling process. A process duration during which the previously applied solution is successively cooled from the carrier substrate starting temperature to the deposition temperature and then optionally kept stable at this final temperature or at intermediate temperatures also typically influences the way in which the perovskite precursors are deposited as a layer and whether crystal formation occurs in the process. Here, the crystalline layer to be produced may be, for example, monocrystalline, multicrystalline, polycrystalline or nanocrystalline. Such a crystalline layer may subsequently react particularly well during heating above the reaction temperature limit to form a perovskite layer or may be converted into a perovskite layer.

According to an embodiment, during the mixing of the solution, a saturation of the solution with the first and second perovskite precursors is set such that, during the subsequent cooling of the solution to the deposition temperature, supersaturation of the solution occurs, in particular supersaturation with the reaction product formed from the two perovskite precursors. In other words, already during the preparation of the solution, so much of the first and/or the second perovskite precursor is dissolved in the solvent that a high saturation of the solution is achieved even at the high mixing temperature then prevailing. Here, the degree of saturation is preferably set to be so high that, during the subsequent cooling of the solution to the lower deposition temperature, on account of the then decreasing temperature-dependent solubility, supersaturation of the solution occurs at least with respect to one of the two perovskite precursors and/or preferably with respect to the reaction product formed from the two perovskite precursors. When such supersaturation is reached, part of the amount of the respective perovskite precursor or of the reaction product contained in the solution then precipitates out of the solution and preferably deposits on the surface of the carrier substrate or on parts of the layer deposited there which have already been produced beforehand. As a result, the deposited layer may be grown particularly quickly.

In order to produce the deposited layer in this case with a high homogeneity and in particular with a constant layer thickness, the carrier substrate is moved in a targeted manner at the same time as the cooling. Here, the movement takes place two-dimensionally, i.e. a position and/or orientation of the carrier substrate is changed in at least two dimensions. In particular, the movement should take place not only in a direction orthogonal to a plane of extent of the carrier substrate, but also transversely to this direction. Here, the movement may take place translationally and/or rotationally. The movement may take place continuously and/or periodically. In particular, the movement may take place in repeating cycles. For example, the movement may take place in the form of a mixture of a repeating back-and-forth movement and a repeating up-and-down movement. On account of such a movement, forces act on the solution applied to the carrier substrate in different directions, in particular in different directions parallel to the surface of the carrier substrate, with the result that the solution is distributed as homogeneously as possible along this surface. Here, the forces may act as inertial forces and/or gravitational forces.

According to an embodiment, the two-dimensional movement is a movement pivoting about at least two different axes. In other words, the carrier substrate is repeatedly pivoted about two different axes during the cooling to the deposition temperature, in order in this way to change the orientation thereof. Here, the two axes run transversely to one another, preferably perpendicularly to one another. The two axes may run within the plane of extent of the carrier substrate or parallel to this plane of extent. The pivoting movement effected in this case is also referred to as wobbling movement or wobbling and enables a particularly effective distribution of the solution along the surface of the carrier substrate.

According to an embodiment, the carrier substrate is temperature-controlled during the application of the solution, during the production of the deposited layer and/or during the heating of the deposited layer by means of a temperature-control device which contacts the carrier substrate in a planar manner. In this case, the temperature-control device may be supplied with power in a controlled manner, in particular with electrical power, in order to be able to be heated to an increased temperature and/or in order to be cooled to a reduced temperature. For this purpose, a power controller may be sufficiently precise in order to temperature-control the carrier substrate to the carrier substrate starting temperature T2 in a targeted manner with the aid of the temperature-control device, then to effect a cooling of the carrier substrate to the deposition temperature T3 by targeted reduction of the heating power, increasing a cooling power or switching off the temperature-control device and/or subsequently to heat the carrier substrate beyond the drying temperature T4. Here, the temperature-control device and/or the controller thereof may be configured to set and/or keep the temperatures mentioned precisely within a tolerance of, for example, less than ±10° C., preferably less than ±5° C. or less than ±3° C. A technical configuration of the temperature-control device and/or of the controller used for the power supply thereof may be relatively simple and therefore enable an inexpensive and/or reliable temperature control of the carrier substrate. For example, the temperature-control device may be configured as a simple heating plate. Alternatively, the temperature-control device may be configured as a thermal station, in which a liquid medium which has been temperature-controlled to a desired temperature is circulated under a plate in order to effect heating or cooling of the plate.

According to an embodiment, the carrier substrate is covered by a cover during the application of the solution and during the movement of the carrier substrate in such a way that the cover bears against the carrier substrate in an annularly sealing manner along edges thereof and a receiving volume is formed between the carrier substrate and the cover, in which receiving volume the solution applied to the carrier substrate is received. In other words, the cover may be configured in such a way that it may bear with its edges against the carrier substrate in a hermetically sealing manner along an annularly closed line. As a result of the fact that the cover bears against the carrier substrate in a hermetically sealing manner at the edges thereof, the solution received in the surrounded receiving volume may be prevented during the movement of the carrier substrate from moving away from the surface of the carrier substrate to be coated and, for example, from dripping off laterally from the carrier substrate.

With the aid of the method according to the first aspect of the invention, a perovskite layer may be formed which may then be used during the manufacturing of a solar cell according to the second aspect of the invention.

Here, the solar cell may be configured as a pure perovskite solar cell. For this purpose, electrical contacts in the form of electrodes must additionally be attached to the perovskite layer formed, with the aid of which electrical charge carriers which are generated by absorption of light in the perovskite layer may be discharged and fed to an external circuit. In addition to the electrical contacts, further layers or components may be formed on the perovskite layer, for example in the form of an electron conductor layer, a hole conductor layer or a transparent, electrically conductive oxide layer (TCO).

Here, the method described herein is suitable in particular for manufacturing perovskite solar cells based on inorganic perovskite layers (e.g., CsPbBr3). However, perovskite solar cells with perovskite layers which contain organic compounds, in particular organometallic compounds, may also be manufactured therewith (e.g., MAPbl3).

According to a further embodiment, the carrier substrate may comprise a first solar cell, wherein the perovskite layer is formed together with the electrical contacts assecond solar cell. In other words, the carrier substrate itself may be a solar cell or comprise a solar cell, with the result that a further solar cell may then be formed on this existing solar cell with the aid of the perovskite layer formed thereon by the method described herein. Here, the first solar cell may be referred to as a bottom solar cell and the second solar cell may be referred to as a top solar cell, wherein both solar cells together form a tandem solar cell.

In particular, the first solar cell may be a silicon solar cell, preferably a solar cell formed on the basis of a silicon wafer. Such silicon solar cells may be produced with technologies which have been established for a long time, have high efficiencies and be very reliable. On such a silicon solar cell, a perovskite solar cell may be formed as a top solar cell. In this case, the two solar cells complement one another well with regard to their respective absorption spectra.

Alternatively, the first solar cell may be a thin-film solar cell, for example on the basis of a III-V semiconductor. As a further example, the first solar cell may be a CdTe solar cell or a CIGS solar cell.

It is pointed out that possible advantages and configurations of embodiments of the invention are described herein in part with reference to a method according to the invention for forming a perovskite layer and in part with reference to a method for manufacturing a solar cell having such a perovskite layer. A person skilled in the art recognizes that the described features may be transferred, adapted, exchanged or modified in a suitable manner in order to arrive at further embodiments of the invention.

### BRIEF DESCRIPTION OF THE DRAWINGS

Embodiments of the invention are described below with reference to the appended drawings, wherein neither the drawings nor the description are to be interpreted as limiting the invention.

FIG. 1(a)-(e) show successive stages of a method according to an embodiment of the invention.

The figures are merely schematic and not true to scale. Identical reference signs designate identical or identically acting features in the different figures.

### DETAILED DESCRIPTION

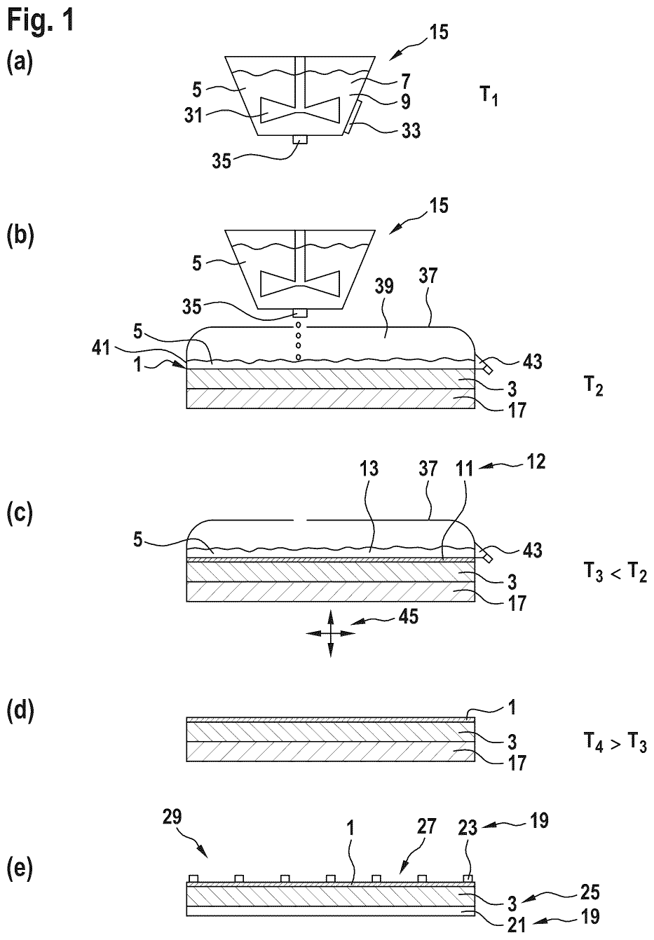

FIG. 1 shows successive stages of a method for forming a perovskite layer 1, with the aid of which a solar cell 29 is ultimately formed.

In a first step (see FIG. 1(a)), a solution 5 is produced by dissolving methylammonium iodide (CH₃NH₃I) as first perovskite precursor 7 and lead acetate trihydrate (Pb(CH₃COO)₂·3H₂O) as second perovskite precursor 9 in an aqueous solution of hydroiodic acid (HI) in a mixing tank 15 and temperature-controlled to a mixing temperature T1 of 70° C. The three substances mentioned here react with one another, the HI also serving to dissolve the other two substances. Instead of lead acetate, lead iodide may also be used. For this purpose, the mixing tank 15 has a stirrer 31 and a heater 33. In addition, a temperature sensor and a controller (not illustrated) may be provided.

In a second step (see FIG. 1(b)), the solution 5 is applied to the carrier substrate 3 through an outlet 35 at the mixing tank 15. Here, the carrier substrate 3 has optionally already been temperature-controlled in advance to a carrier substrate starting temperature T2 of 65° C. For this purpose, a temperature-control device 17, for example in the form of a heating plate, contacts the carrier substrate 3 in a planar manner along the rear side surface thereof. At the front side surface thereof, a receiving volume 39 is created with the aid of a cover 37, into which receiving volume the solution 5 is introduced. Here, the cover 37 closes with its edges 41 in a hermetically sealing manner with a front side surface of the carrier substrate 3.

In a third step (see FIG. 1(c)), the carrier substrate 3 is then moved together with the applied solution 5 in a two-dimensional movement. This is symbolized in the figure by movement arrows 45. Simultaneously, the carrier substrate 3 and the applied solution 5 are successively cooled to a deposition temperature T3 of less than 40° C. Since a solubility of the two perovskite precursors 7, 9 or of the reaction products formed therefrom in the solution 5 decreases during this temperature reduction, the degree of saturation thereof increases until, at the latest when supersaturation is reached, part of the perovskite precursors 7, 9 or reaction products contained in the solution 5 precipitates out and deposits on the front side surface of the carrier substrate 3. As a result, a deposited layer 11 is formed on the carrier substrate 3. On account of the two-dimensional, preferably wobbling movement of the carrier substrate 3, this deposited layer 11 is produced with a high homogeneity and layer thickness. Here, process parameters are selected such that the deposited layer 11 is produced as a crystalline layer 12.

After the deposited layer 11 has reached a sufficient layer thickness, an excess, non-deposited proportion 13 of the solution 5 is discharged from a discharge nozzle 43 and therefore removed from the carrier substrate 3.

Subsequently, in a fourth step (see FIG. 1(d)), the deposited layer 11 is heated together with the carrier substrate 3 with the aid of the temperature-control device 17 above a drying temperature T4 of, for example, 50° C. As a result, remaining solvent is evaporated. Furthermore, a chemical reaction occurs between possibly remaining residues of the two perovskite precursors 7, 9 and ultimately possibly proceeding from a previously formed intermediate (MA4Pbl6·2H2O) for forming the perovskite layer 1 from methylammonium lead iodide (MAPbl₃).

In order ultimately to manufacture a solar cell 29 with the perovskite layer 1 formed in this way, in a fifth step (see FIG. 1(e)), electrical contacts 19 in the form of an electrical rear contact 21 and an electrical front contact 23 are produced which electrically contact the perovskite layer 1 on opposite sides. In the example illustrated, for this purpose, the rear contact 21 may be applied to a side of the carrier substrate 3 opposite the perovskite layer 1 and electrically connected to a possibly previously produced conductive layer (not illustrated). Alternatively and usually preferably for practical applications, a rear contact 21 may be formed which acts directly on such a conductive layer, which is located between the carrier substrate 3 and the perovskite layer 1, or on the rear side of the perovskite layer 1. Here, the rear contact 21 may be provided, for example, in the form of a metal layer. The front contact 23 may be provided in the form of a multiplicity of thin finger-like metal contacts. Alternatively or additionally, the front contact 23 may be formed with the aid of an electrically conductive, transparent layer. Overall, in this way, a solar cell 29 in the form of a perovskite solar cell may be formed. The side facing the sun may possibly also be that side which is covered with the glass substrate. In this case, the metal layer may act as rear contact and possibly be formed over the entire area.

Alternatively to this, the carrier substrate 3 may be formed by an already preprocessed first solar cell 25 instead of with a glass substrate. For example, this first solar cell 25 may be an efficient wafer-based silicon solar cell. On a front side surface of this first solar cell 25, the perovskite layer 1 may then be produced and in this case form a second solar cell 27. The two solar cells 25, 27 are possibly electrically connected to one another via a conductive layer (not illustrated) formed therebetween and may thereby form overall a solar cell 29 in the form of a tandem solar cell.

It is pointed out that both the method steps and the structures produced thereby have been illustrated and described merely in a greatly simplified manner. In a real implementation, further method steps may be used and/or further structures may be produced, for example, in the form of additional layers, electrodes or the like.

In addition, it is pointed out that the earlier patent DE 10 2006 007 446 B3 describes, inter alia, a device which is configured in a suitable manner for carrying out embodiments of the method described herein. The method described herein may therefore be carried out using such a device. Features as have been described for the device may be applied analogously to the method described herein. The content of the earlier patent is incorporated herein in its entirety by reference.

In addition, it is pointed out that the proposed method may also be carried out as part of a two-stage process. In this case, with the proposed method, first a first sublayer may be produced, to which a further sublayer may then be applied in a second subprocess. In this case, the two sublayers may possibly only subsequently be heated to an increased temperature at which a chemical reaction and/or a reformation of the precursors and/or reaction products contained in the two sublayers occurs, with the result that the perovskite layer ultimately forms. Here, the second sublayer may be produced with the same or a similar method as the first sublayer. Alternatively, however, the second sublayer may also be produced with a different method, such as, for example, spinning or rolling.

Finally, it should be pointed out that terms such as “having”, “comprising”, etc. do not exclude any other elements or steps and terms such as “a” or “an” do not exclude a multiplicity. Furthermore, it should be pointed out that features or steps which have been described with reference to one of the above exemplary embodiments may also be used in combination with other features or steps of other exemplary embodiments described above. Reference signs in the claims should not be regarded as a restriction.

### LIST OF REFERENCE SIGNS

1 PEROVSKITE LAYER
3 carrier substrate
5 solution
7 first perovskite precursor
9 second perovskite precursor
11 deposited layer
12 crystalline layer
13 non-deposited proportion of the solution
15 mixing tank
17 heating plate
19 electrical contacts
21 electrical rear contact
23 electrical front contact
25 first solar cell
27 second solar cell
29 solar cell
31 stirrer
33 temperature-control device
35 outlet
37 cover
39 receiving volume
41 edges
43 discharge nozzle
45 movement arrows
T1 mixing temperature
T2 carrier substrate starting temperature
T3 deposition temperature
T4 drying temperature

1-15. (canceled)

16. A method for forming a perovskite layer on a carrier substrate, comprising:
mixing a solution which contains a first and a second perovskite precursor at a mixing temperature,
applying the solution to the carrier substrate,
moving the carrier substrate together with the applied solution in a two-dimensional movement, wherein the carrier substrate is successively displaced transversely in different directions and/or rotated or pivoted rotationally about different axes, and simultaneously cooling the carrier substrate together with the applied solution to a deposition temperature below the mixing temperature in order to produce a deposited layer which contains both the first and the second perovskite precursor and/or a reaction product from the two perovskite precursors on the carrier substrate.

17. The method according to claim 16,
wherein the solution is aqueous and wherein the first and the second perovskite precursor and/or the reaction product are soluble in aqueous solution.

18. The method according to claim 16,
wherein the first perovskite precursor contains cesium, methylammonium or formamidinium.

19. The method according to claim 16,
wherein the first perovskite precursor contains methylammonium iodide.

20. The method according to claim 16,
wherein the second perovskite precursor contains lead.

21. The method according to claim 16,
wherein the second perovskite precursor contains lead acetate and/or a lead halide.

22. The method according to claim 16,
wherein the solution contains hydrogen halide.

23. The method according to claim 16,
wherein the solution is mixed separately from the carrier substrate in a mixing tank and temperature-controlled to the mixing temperature.

24. The method according to claim 16,
wherein during the production of the deposited layer, process parameters including a process duration and a temporal temperature profile during the cooling to the deposition temperature are selected such that the deposited layer is produced as a crystalline layer.

25. The method according to claim 16,
wherein during the mixing of the solution, a saturation of the solution with the first and second perovskite precursors is set such that, during the subsequent cooling of the solution to the deposition temperature, supersaturation of the solution occurs.

26. The method according to claim 16,
wherein the two-dimensional movement is a movement pivoting about at least two different axes.

27. The method according to claim 16,
wherein the carrier substrate is temperature-controlled during the application of the solution, during the production of the deposited layer and/or during a heating of the deposited layer by means of a temperature-control device which contacts the carrier substrate in a planar manner.

28. The method according to claim 16,
wherein the carrier substrate is covered by a cover during the application of the solution and during the movement of the carrier substrate in such a way that the cover bears against the carrier substrate in an annularly sealing manner along the edges thereof and a receiving volume is formed between the carrier substrate and the cover, in which receiving volume the solution applied to the carrier substrate is received.

29. A method for manufacturing a solar cell, comprising
forming a perovskite layer on a surface of a carrier substrate by means of the method according to claim 16, and
forming electrical contacts for discharging electrical charge carriers from the perovskite layer.

30. The method according to claim 29,
wherein the carrier substrate comprises a first solar cell and wherein the perovskite layer is formed together with the electrical contacts as a second solar cell.
